(19) United States
(12) Patent Application Publication
(10) Pub. No.: US 2021/0408178 A1
(43) Pub. Date: Dec. 30, 2021

(54) DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventor: Xingyu ZHOU, Shenzhen (CN)

(73) Assignee: Shenzhen China Star Optoelectronics Semiconductor Display Technology Co., Ltd., Shenzhen (CN)

(21) Appl. No.: 16/647,505

(22) PCT Filed: Feb. 13, 2020
(86) PCT No.: PCT/CN2020/075128

§ 371 Date: Mar. 15, 2020

(30) Foreign Application Priority Data
Jan. 16, 2020 (CN) 202010045370.2

(51) Int. Cl. H01L 27/32

(52) U.S. Cl. CPC H01L 27/3246; H01L 2227/323

(57) ABSTRACT

The present disclosure provides a display panel and a manufacturing method thereof. The display panel includes at least a part of metal layer disposed in a bonding area. The metal layer includes a first sub-metal layer, a second sub-metal layer, and a third sub-metal layer disposed in sequence and in a stack. A material used as the first sub-metal layer and the third sub-metal layer is one of molybdenum, titanium, or molybdenum-titanium alloy, and a material used as the second sub-metal layer is copper. The display panel provided by the present disclosure can solve problems that metal silver in the bonding area cannot be exposed outside and metal copper exposed outside is easily oxidized.

### FIELD OF INVENTION

The present disclosure relates to the field of display technologies, and more particularly, to a display panel and a manufacturing method thereof.

### BACKGROUND OF INVENTION

Anodes in panels of top emission organic light-emitting diodes (OLEDs) usually use silver (Ag) alloys, which easily oxidize after long-time exposure, and pads in a peripheral bonding area usually all need to remove Ag. For large size panels, source/drain metals are usually processed using copper (Cu), which is also a metal prone to oxidation and cannot be exposed outside.

Technical problem: an embodiment of the present disclosure provides a display panel and a manufacturing method of a structure of the display panel to solve the problem that metals in a bonding area exposed outside are prone to oxidation.

### SUMMARY OF INVENTION

An embodiment of the present disclosure provides a display panel which has a pixel area and a bonding area disposed adjacent to the pixel area. The display panel comprises:

a metal layer, wherein at least a part of the metal layer is disposed in the bonding area, and the metal layer comprises:

a first sub-metal layer comprising a first surface and a second surface disposed opposite to the first surface;

a second sub-metal layer disposed on the first surface; and

a third sub-metal layer disposed on one side of the second sub-metal layer away from the first surface;

wherein a material used as the first sub-metal layer and the third sub-metal layer is one of molybdenum, titanium, or molybdenum-titanium alloy, and a material used as the second sub-metal layer is copper.

In some embodiments, the display panel further comprises an interlayer insulating layer, a passivation layer, a planarization layer, and a pixel definition layer, wherein the metal layer in the bonding area is disposed on the interlayer insulating layer, the passivation layer covers the metal layer and the interlayer insulating layer, the planarization layer is disposed on the passivation layer, and the pixel definition layer is disposed on the planarization layer; and

defining a groove in the passivation layer, the planarization layer, and the pixel definition layer, wherein the groove extends from a side surface of the pixel definition layer away from the planarization layer to a side surface of the third sub-metal layer of the metal layer away from the first surface.

In some embodiments, the display panel further comprises a conductor layer, wherein the interlayer insulating layer in the pixel area is disposed on the conductor layer, the interlayer insulating layer in the pixel area is provided with a first contact hole and a second contact hole, the metal layer in the pixel area is connected to the conductor layer through the first contact hole and the second contact hole after patterning, and the passivation layer covers the metal layer and the interlayer insulating layer.

In some embodiments, wherein the conductor layer further comprises a semiconductor layer, the semiconductor layer is disposed in the conductor layer, and a gate insulating layer and a gate electrode metal layer are sequentially disposed on the semiconductor layer.

In some embodiments, wherein a material used as the semiconductor layer is metal oxide, and thicknesses of the semiconductor layer and the conductor layer range from 100 Å to 1000 Å.

In some embodiments, wherein a material used as the gate insulating layer is silicon oxide derivatives, silicon nitride derivatives, or combinations thereof.

In some embodiments, wherein a material used as the gate electrode metal layer is molybdenum, aluminum, copper, titanium, or alloys thereof.

In some embodiments, wherein a thickness of the second sub-metal layer ranges from 5000 Å to 10000 Å, and thicknesses of the first sub-metal layer and the third sub-metal layer range from 100 Å to 500 Å.

In some embodiments, wherein a material of the passivation layer and the interlayer insulating layer is silicon oxide derivatives, silicon nitride derivatives, or combinations thereof, a thickness of the interlayer insulating layer ranges from 2000 Å to 10000 Å, and a thickness of the passivation layer ranges from 1000 Å to 5000 Å.

In some embodiments, wherein a material of the planarization layer is a photoresist material, and a thickness of the planarization layer ranges from 0.5 μm to 3 μm.

An embodiment of the present disclosure provides a manufacturing method of a display panel. The method comprises:

providing a first sub-metal layer comprising a first surface and a second surface disposed opposite to the first surface;

disposing a second sub-metal layer on the first surface; and

disposing a third sub-metal layer on the second sub-metal layer;

wherein the first sub-metal layer, the second sub-metal layer, and the third sub-metal layer form a metal layer, the display panel has a pixel area and a bonding area disposed adjacent to the pixel area, at least a part of the metal layer is disposed in the bonding area, a material of the first sub-metal layer and the third sub-metal layer is one of molybdenum, titanium, or molybdenum-titanium alloy, and a material of the second sub-metal layer is copper.

In some embodiments, the step of providing the first sub-metal layer comprises:

depositing a conductor layer in the pixel area;

depositing an interlayer insulating layer on the conductor layer; and

depositing the first sub-metal layer on the interlayer insulating layer;

wherein after the first sub-metal layer, the second sub-metal layer, and the third sub-metal layer forming the metal layer, the method further comprises:

depositing a passivation layer, a planarization layer, and a pixel electrode layer on the metal layer in sequence;

etching the overall pixel electrode layer in the bonding area;

depositing a pixel definition layer after finishing the etching process; and

defining a groove in the passivation layer, the planarization layer, and the pixel definition layer by photolithography or etching, wherein the groove extends from a surface of the pixel definition layer to a side surface of the third sub-metal layer of the metal layer away from the first surface.

In some embodiments, wherein after depositing the interlayer insulating layer on the conductor layer, the method further comprises first contact hole a first contact hole and a second contact hole in the interlayer insulating layer in the pixel area by photolithography or etching to make the metal layer in the pixel area connected to the conductor layer through the first contact hole and the second contact hole.

In some embodiments, wherein the conductor layer further comprises a semiconductor layer, the semiconductor layer is disposed in the conductor layer, and a gate insulating layer and a gate electrode metal layer are sequentially disposed on the semiconductor layer.

In some embodiments, wherein a material used as the semiconductor layer is metal oxide, and thicknesses of the semiconductor layer and the conductor layer range from 100 Å to 1000 Å.

In some embodiments, wherein a material used as the gate insulating layer is silicon oxide derivatives, silicon nitride derivatives, or combinations thereof.

In some embodiments, wherein a material used as the gate electrode metal layer is molybdenum, aluminum, copper, titanium, or alloys thereof.

In some embodiments, wherein a thickness of the second sub-metal layer ranges from 5000 Å to 10000 Å, and thicknesses of the first sub-metal layer and the third sub-metal layer range from 100 Å to 500 Å.

In some embodiments, wherein a material of the passivation layer and the interlayer insulating layer is silicon oxide derivatives, silicon nitride derivatives, or combinations thereof, a thickness of the interlayer insulating layer ranges from 2000 Å to 10000 Å, and a thickness of the passivation layer ranges from 1000 Å to 5000 Å.

In some embodiments, wherein a material of the planarization layer is a photoresist material, and a thickness of the planarization layer ranges from 0.5 μm to 3 μm.

Beneficial effect: a display panel provided in an embodiment of the present disclosure has a pixel area and a bonding area disposed adjacent to the pixel area. The display panel comprises a metal layer. Wherein, at least a part of the metal layer is disposed in the bonding area, and the metal layer comprises: a first sub-metal layer including a first surface and a second surface disposed opposite to the first surface; a second sub-metal layer disposed on the first surface; and a third sub-metal layer disposed on one side of the second sub-metal layer away from the first surface. Wherein, a material used as the first sub-metal layer and the third sub-metal layer is one of molybdenum, titanium, or molybdenum-titanium alloy, and a material used as the second sub-metal layer is copper. The display panel provided in the embodiment of the present disclosure protects metal copper and prevents the metal copper from oxidization by adding a sub-metal layer structure on the metal copper layer. Furthermore, it makes the bonding area have no metal silver structure and also prevents the oxidization problem of metal silver by etching overall pixel electrode layer in the bonding area. Therefore, the display panel provided by the present disclosure can solve the problem that metals in the bonding area exposed outside are prone to oxidation.

### DESCRIPTION OF DRAWINGS

The accompanying figures to be used in the description of embodiments of the present disclosure will be described in brief to more clearly illustrate the technical solutions of the embodiments. The accompanying figures described below are only part of the embodiments of the present disclosure, from which those skilled in the art can derive further figures without making any inventive efforts.

FIG. 1 is a schematic diagram of a display panel according to an embodiment of the present disclosure.

FIG. 2 is a schematic structural diagram of a metal layer according to an embodiment of the present disclosure.

FIG. 3 is a schematic structural diagram of a display panel according to an embodiment of the present disclosure.

FIG. 4 is a first flowchart of a manufacturing method of a display panel according to an embodiment of the present disclosure.

FIG. 5 is a second flowchart of a manufacturing method of a display panel according to an embodiment of the present disclosure.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure. Based on the embodiments in the present disclosure, all other embodiments obtained by those skilled in the art without creative efforts are within the scope of the present disclosure.

It should be noted that in the description of the present disclosure, it should be understood that terms such as “upper”, “lower”, “front”, “rear”, “left”, “right”, “inside”, “outside”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure.

An embodiment of the present disclosure provides a display panel. The following describes the display panel in detail.

Referring to FIG. 1, FIG. 1 is a schematic diagram of a display panel 10 according to an embodiment of the present disclosure. The display panel 10 has a pixel area 10a and a bonding area 10b disposed adjacent to the pixel area 10a.

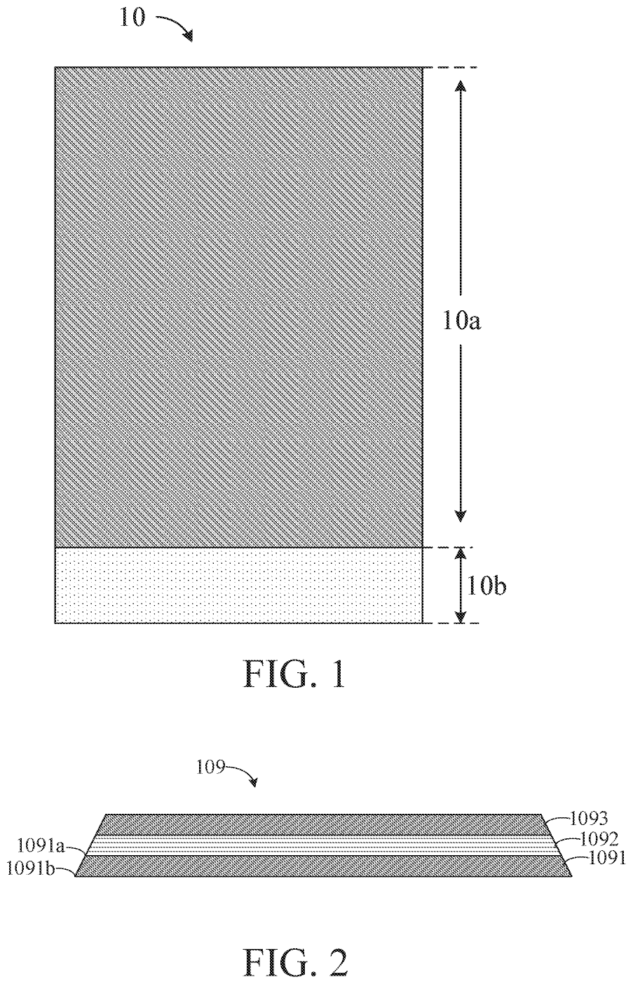

Referring to FIG. 2, FIG. 2 is a schematic structural diagram of a metal layer 109 in the display panel 10 according to an embodiment of the present disclosure. Wherein, the display panel 10 comprises a metal layer 109, and at least a part of the metal layer 109 is disposed in the bonding area. The metal layer 109 comprises a first sub-metal layer 1091, a second sub-metal layer 1092, and a third sub-metal layer 1093.

The first sub-metal layer 1091 includes a first surface 1091a and a second surface 1091b disposed opposite to the first surface 1091a. The second sub-metal layer 1092 is disposed on the first surface 1091a. The third sub-metal layer 1093 is disposed on one side of the second sub-metal layer 1092 away from the first surface 1091a.

Wherein, a material used as the first sub-metal layer 1091 and the third sub-metal layer 1093 is one of molybdenum (Mo), titanium (Ti), or molybdenum-titanium alloy (Mo—Ti), and a material used as the second sub-metal layer 1092 is copper (Cu). Specifically, the material used as the first sub-metal layer 1091 and the third sub-metal layer 1093 is molybdenum-titanium alloy (Mo—Ti) and the material used as the second sub-metal layer 1092 is copper (Cu) to form a three-layered metal layer structure of Mo—Ti/Cu/Mo—Ti. When etching a pixel electrode layer on the third sub-metal layer 1093 in the pixel area 10a, the material used as the third sub-metal layer 1093 is one of molybdenum (Mo), titanium (Ti), or molybdenum-titanium alloy (Mo—Ti), which can provide an anti-corrosion effect, and the third sub-metal layer 1093 can protect the second sub-metal layer 1092 to prevent the second sub-metal layer 1092 from oxidization.

Wherein, a thickness of the second sub-metal layer 1092 ranges from 5000 Å to 10000 Å. Specifically, the thickness of the second sub-metal layer 1092 may be 5000 Å, 6000 Å, 7000 Å, 8000 Å, 9000 Å, or 10000 Å. Thicknesses of the first sub-metal layer 1091 and the third sub-metal layer 1093 range from 100 Å to 500 Å. Specifically, the thicknesses of the first sub-metal layer 1091 and the third sub-metal layer 1093 may be 100 Å, 200 Å, 300 Å, 400 Å, or 500 Å.

It should be noted that the first surface 1091a can be an upper surface of the first sub-metal layer 1091, and the second surface 1091b can be a lower surface of the first sub-metal layer 1091. Of course, the first surface 1091a can also be the lower surface of the first sub-metal layer 1091, and the second surface 1091b can be the upper surface of the first sub-metal layer 1091. In the case without specific description in the embodiment of the present disclosure, the first surface 1091a is the upper surface of the first sub-metal layer 1091 and the second surface 1091b is the lower surface of the first sub-metal layer 1091 by default.

The display panel 10 provided by the embodiment of the present disclosure comprises the metal layer 109, and at least a part of the metal layer 109 is disposed in the bonding area 10b. The metal layer 109 comprises the first sub-metal layer 1091, the second sub-metal layer 1092, and the third sub-metal layer 1093. The first sub-metal layer 1091 includes the first surface 1091a and the second surface 1091b disposed opposite to the first surface 1091a. The second sub-metal layer 1092 is disposed on the first surface 1091a. The third sub-metal layer 1093 is disposed on one side of the second sub-metal layer 1092 away from the first surface 1091a. Wherein, a material used as the first sub-metal layer 1091 and the third sub-metal layer 1093 is one of molybdenum (Mo), titanium (Ti), or molybdenum-titanium alloy (Mo—Ti), and a material used as the second sub-metal layer 1092 is copper (Cu). By disposing the third sub-metal layer 1093 on the second sub-metal layer 1092, when etching a pixel electrode layer 112 on the third sub-metal layer 1093 in the pixel area 10a, the third sub-metal layer 1093 uses the material of molybdenum (Mo), titanium (Ti), or molybdenum-titanium alloy (Mo—Ti) to provide an anti-corrosion effect, and the third sub-metal layer 1093 can protect the second sub-metal layer 1092 to prevent the second sub-metal layer 1092 from oxidization.

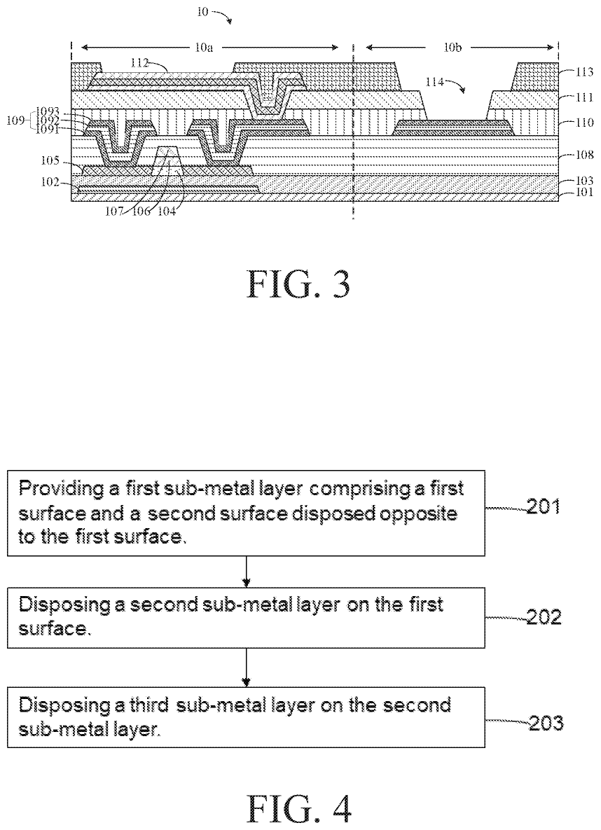

Referring to FIG. 3, FIG. 3 is a schematic structural diagram of a display panel 10 according to an embodiment of the present disclosure. Wherein, the display panel 10 further comprises a glass substrate 101, a light-shielding layer 102, a buffer layer 103, a semiconductor layer 104, a conductor layer 105, a gate insulating layer 106, a gate electrode metal layer 107, an interlayer insulating layer 108, a passivation layer 110, a planarization layer 111, a pixel electrode layer 112, and a pixel definition layer 113. The light-shielding layer 102, the buffer layer 103, the semiconductor layer 104, the conductor layer 105, the gate insulating layer 106, the gate electrode metal layer 107, the interlayer insulating layer 108, the passivation layer 110, the planarization layer 111, the pixel electrode layer 112, and the pixel definition layer 113 are deposited in sequence on the glass substrate 101 and are disposed in a stack.

Wherein, a material used as the light-shielding layer 102 is a metal or an alloy. Specifically, the material used as the light-shielding layer 102 may be molybdenum (Mo), aluminum (Al), copper (Cu), titanium (Ti), or alloys of these metals. A thickness of the light-shielding layer 102 ranges from 500 Å to 10000 Å. Specifically, the thickness of the light-shielding layer 102 may be 500 Å, 600 Å, 1000 Å, 3000 Å, 5000 Å, 7000 Å, 9000 Å, or 10000 Å.

Wherein, a material used as the buffer layer 103 is silicon oxide derivatives, silicon nitride derivatives, or combinations of these materials. A thickness of the buffer layer 103 ranges from 1000 Å to 5000 Å. Specifically, the thickness of the buffer layer 103 may be 1000 Å, 2000 Å, 3000 Å, 4000 Å, or 5000 Å.

Wherein, the conductor layer 105 further comprises the semiconductor layer 104, the semiconductor layer 104 is disposed in the conductor layer 105, and the gate insulating layer 106 and the gate electrode metal layer 107 are sequentially disposed on the semiconductor layer 104.

Wherein, a material used as the semiconductor layer 104 is metal oxide. Specifically, the material used as the semiconductor layer 104 is one of indium gallium zinc oxide (IGZO), indium zinc tin oxide (IZTO), indium gallium zinc tin oxide (IGZTO), indium tin oxide (ITO), indium zinc oxide (IZO), indium aluminum zinc oxide (IAZO), indium gallium tin oxide (IGTO), or antimony tin oxide (ATO). Wherein, thicknesses of the semiconductor layer 104 and the conductor layer 105 range from 100 Å to 1000 Å. Specifically, the thicknesses of the semiconductor layer 104 and the conductor layer 105 may be 100 Å, 200 Å, 300 Å, 500 Å, 700 Å, 900 Å, or 1000 Å.

Wherein, a material used as the gate insulating layer 106 is silicon oxide derivatives, silicon nitride derivatives, or combinations of these materials. A thickness of the gate insulating layer 106 ranges from 1000 Å to 3000 Å. Specifically, the thickness of the gate insulating layer 106 may be 1000 Å, 1500 Å, 2000 Å, 2500 Å, or 3000 Å.

Wherein, a material used as the gate electrode metal layer 107 may be molybdenum (Mo), aluminum (Al), copper (Cu), titanium (Ti), or alloys of these metals. A thickness of the gate electrode metal layer 107 ranges from 2000 Å to 8000 Å. Specifically, the thickness of the gate electrode metal layer 107 may be 2000 Å, 3000 Å, 4000 Å, 5000 Å, 6000 Å, 7000 Å, or 8000 Å.

Wherein, a material used as the interlayer insulating layer 108 is silicon oxide derivatives, silicon nitride derivatives, or combinations of these materials. A thickness of the interlayer insulating layer 108 ranges from 2000 Å to 10000 Å. Specifically, the thickness of the interlayer insulating layer 108 is 2000 Å, 4000 Å, 6000 Å, 8000 Å, or 10000 Å. The interlayer insulating layer 108 in the pixel area 10a is disposed on the conductor layer 105, and the interlayer insulating layer 108 in the pixel area 10a is provided with a first contact hole and a second contact hole.

Wherein, the metal layer 109 in the bonding area 10b is disposed on the interlayer insulating layer 108 and partially covers the interlayer insulating layer 108. The metal layer 109 in the pixel area 10a is connected to the conductor layer 105 through the first contact hole and the second contact hole after patterning.

Wherein, a material used as the passivation layer 110 is silicon oxide derivatives, silicon nitride derivatives, or combinations of these materials. A thickness of the passivation layer 110 ranges from 1000 Å to 5000 Å. Specifically, the thickness of the passivation layer 110 may be 1000 Å, 2000 Å, 3000 Å, 4000 Å, or 5000 Å. The passivation layer 110 covers the metal layer 109 and the interlayer insulating layer 108. The passivation layer 110, the planarization layer 111, and the pixel definition layer 112 in the bonding area 10b are provided with a groove 114, and the groove 114 extends from one side surface of the pixel definition layer 113 away from the planarization layer 111 to one side surface of the third sub-metal layer 1093 of the metal layer 109 away from the first surface 1091a.

Wherein, a material of the planarization layer 111 is a photoresist material. A thickness of the planarization layer 111 ranges from 0.5 μm to 3 μm. Specifically, the thickness of the planarization layer 111 may be 0.5 μm, 1 μm, 1.5 μm, 2 μm, 2.5 μm, or 3 μm.

The display panel 10 provided by the embodiment of the present disclosure comprises the glass substrate 101, the light-shielding layer 102, the buffer layer 103, the semiconductor layer 104, the conductor layer 105, the gate insulating layer 106, the gate electrode metal layer 107, the interlayer insulating layer 108, the metal layer 109, the passivation layer 110, the planarization layer 111, the pixel electrode layer 112, and the pixel definition layer 113. Wherein, by designing the metal layer 109 as a three-layered structure, that is, by disposing the third sub-metal layer 1093 on the second sub-metal layer 1092, when etching a pixel electrode layer 112 on the third sub-metal layer 1093 in the pixel area 10a, the third sub-metal layer 1093 uses the material of molybdenum (Mo), titanium (Ti), or molybdenum-titanium alloy (Mo—Ti) to provide an anti-corrosion effect, and the third sub-metal layer 1093 can protect the second sub-metal layer 1092 to prevent the second sub-metal layer 1092 from oxidization. In addition, there is no metal silver (Ag) structure in the bonding area 10b, so the problem of oxidation of Ag is also prevented.

An embodiment of the present disclosure provides a manufacturing method of a display panel. The following describes the manufacturing method of the display panel in detail. Referring to FIG. 4, FIG. 4 is a first flowchart of a manufacturing method of a display panel according to an embodiment of the present disclosure.

Step 201: providing a first sub-metal layer comprising a first surface and a second surface disposed opposite to the first surface.

Step 202: disposing a second sub-metal layer on the first surface.

Step 203: disposing a third sub-metal layer on the second sub-metal layer.

Wherein, the first sub-metal layer, the second sub-metal layer, and the third sub-metal layer form a metal layer. At least a part of the metal layer is disposed in the bonding area.

The manufacturing method of the display panel provided by the embodiment of the present disclosure, by disposing the third sub-metal layer on the second sub-metal layer, when etching a pixel electrode layer on the third sub-metal layer in the pixel area, the third sub-metal layer uses the material of molybdenum (Mo), titanium (Ti), or molybdenum-titanium alloy (Mo—Ti) to provide an anti-corrosion effect, and the third sub-metal layer can protect the second sub-metal layer to prevent the second sub-metal layer from oxidization.

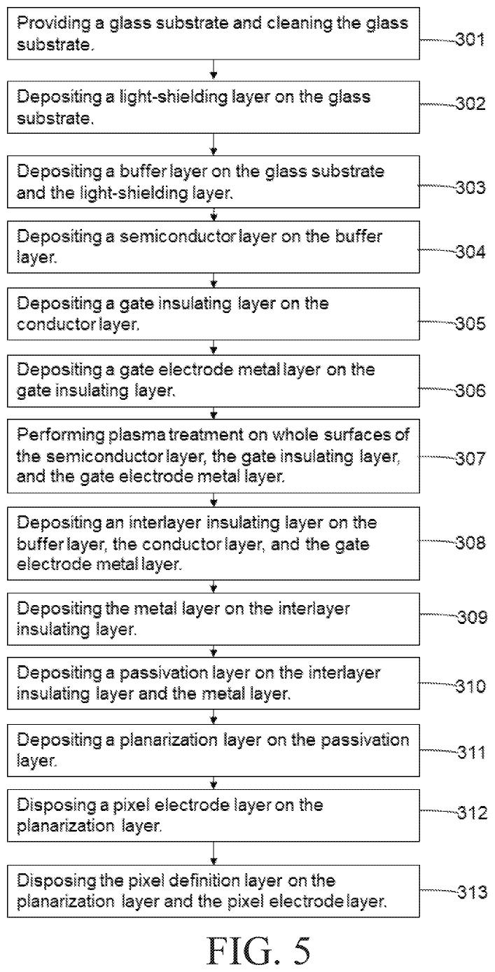

Referring to FIG. 5, FIG. 5 is a second flowchart of a manufacturing method of a display panel according to an embodiment of the present disclosure.

Step 301: providing a glass substrate and cleaning the glass substrate.

Step 302: depositing a light-shielding layer on the glass substrate.

Step 303: depositing a buffer layer on the glass substrate and the light-shielding layer.

Wherein, the buffer layer covers the glass substrate and the light-shielding layer.

Step 304: depositing a semiconductor layer on the buffer layer.

Wherein, a pattern is manufactured on the semiconductor layer by photolithography or etching.

Photolithography is a process of performing coating, soft-baking, exposure, developing, and hard-baking on chips, such as silicon wafer, using light to etch a predetermined pattern. Etching is a technique using chemical reactions or physical impact to remove materials. In the embodiment of the present disclosure, a material of the semiconductor layer can be coated on the buffer layer and then a pattern of the semiconductor layer can be obtained by photolithography, or after the material of the semiconductor layer is deposited on the buffer layer, the semiconductor layer is patterned by etching.

Step 305: depositing a gate insulating layer on the conductor layer.

Step 306: depositing a gate electrode metal layer on the gate insulating layer.

Wherein, a pattern of the gate electrode metal layer is manufactured by photolithography or etching, and then the pattern of the gate electrode metal layer is used as a mask to manufacture the gate insulating layer by photolithography or etching to etch the gate insulating layer which is not covered by the gate electrode metal layer.

Step 307: performing plasma treatment on whole surfaces of the semiconductor layer, the gate insulating layer, and the gate electrode metal layer.

Wherein, plasma is an ionized gaseous substance composed of negatively charged particles (negative ions and electrons), positively charged particles (positive ions), and uncharged particles. It is usually juxtaposed with the solid, liquid, and gaseous states of matter, and is called the fourth state of matter. Using plasma technique, a new surface structure can be obtained on the semiconductor layer. Specifically, for the semiconductor layer without protection of the gate insulating layer and the gate electrode metal layer on top, a resistance thereof will decrease after plasma treatment and the semiconductor layer will form a conductor layer. The semiconductor layer under the gate insulating layer is not treated, maintains characteristics of semiconductor, and is used as channels of thin film transistors (TFTs). In the display panel, thin film transistors can be used as a switching device or a driving device. Therefore, the channels forming the thin film transistors can act as path channels for mobile charge carriers.

Step 308: depositing an interlayer insulating layer on the buffer layer, the conductor layer, and the gate electrode metal layer.

Wherein, a first contact hole and a second contact hole are etched in the interlayer insulating layer.

Step 309: depositing the metal layer on the interlayer insulating layer.

Wherein, the metal layer in the pixel area after patterning is connected to the conductor layer through the first contact hole and the second contact hole which are disposed in the interlayer insulating layer.

Step 310: depositing a passivation layer on the interlayer insulating layer and the metal layer.

Wherein, the passivation layer covers the metal layer and the interlayer insulating layer.

Step 311: depositing a planarization layer on the passivation layer.

Wherein, grooves penetrating through the passivation layer and the planarization layer are obtained by photolithography.

Step 312: disposing a pixel electrode layer on the planarization layer.

Wherein, the pixel electrode layer in the pixel area is connected to the metal layer through a groove in the pixel area. The groove in the pixel area extends from a side surface of the planarization layer away from the passivation layer to a side surface of the third sub-metal layer of the metal layer away from the first surface. The overall pixel electrode layer in the bonding area is etched to form a groove in the bonding area. The groove in the bonding area extends from a side surface of a pixel definition layer away from the planarization layer to a side surface of the third sub-metal layer of the metal layer away from the first surface. The method makes the bonding area have no metal silver (Ag) structure and also prevents the oxidization problem of metal silver (Ag) by etching overall pixel electrode layer in the bonding area.

Step 313: disposing the pixel definition layer on the planarization layer and the pixel electrode layer.

Wherein, after disposing the pixel definition layer, a groove is defined in the pixel definition layer in the pixel area to deposit a cathode layer, and then encapsulation is performed.

The manufacturing method of the display panel provided by the embodiment of the present disclosure by disposing a three-layered structure of metal layer, that is, by disposing the third sub-metal layer on the second sub-metal layer, when etching the pixel electrode layer on the third sub-metal layer in the pixel area, the third sub-metal layer uses the material of molybdenum (Mo), titanium (Ti), or molybdenum-titanium alloy (Mo—Ti) to provide an anti-corrosion effect, and the third sub-metal layer can protect the second sub-metal layer to prevent the second sub-metal layer from oxidization.

The display panel and the manufacturing method of the display panel provided by the embodiment of the present disclosure are described in detail above. The specific examples are applied in the description to explain the principle and implementation of the disclosure. The description of the above embodiments is only for helping to understand the technical solution of the present disclosure and its core ideas. Meanwhile, for those skilled in the art, the range of specific implementation and application may be changed according to the ideas of the present disclosure. In summary, the content of the specification should not be construed as causing limitations to the present disclosure.

What is claimed is:

1. A display panel having a pixel area and a bonding area disposed adjacent to the pixel area, comprising:
a metal layer, wherein at least a part of the metal layer is disposed in the bonding area, and the metal layer comprises:
a first sub-metal layer comprising a first surface and a second surface disposed opposite to the first surface;
a second sub-metal layer disposed on the first surface; and
a third sub-metal layer disposed on one side of the second sub-metal layer away from the first surface;
wherein a material used as the first sub-metal layer and the third sub-metal layer is one of molybdenum, titanium, or molybdenum-titanium alloy, and a material used as the second sub-metal layer is copper.

2. The display panel according to claim 1, further comprising an interlayer insulating layer, a passivation layer, a planarization layer, and a pixel definition layer, wherein the metal layer in the bonding area is disposed on the interlayer insulating layer, the passivation layer covers the metal layer and the interlayer insulating layer, the planarization layer is disposed on the passivation layer, and the pixel definition layer is disposed on the planarization layer; and
the passivation layer, the planarization layer, and the pixel definition layer in the bonding area are provided with a groove, and the groove extends from one side surface of the pixel definition layer away from the planarization layer to one side surface of the third sub-metal layer of the metal layer away from the first surface.

3. The display panel according to claim 2, further comprising a conductor layer, wherein the interlayer insulating layer in the pixel area is disposed on the conductor layer, the interlayer insulating layer in the pixel area is provided with a first contact hole and a second contact hole, the metal layer in the pixel area is connected to the conductor layer through the first contact hole and the second contact hole after patterning, and the passivation layer covers the metal layer and the interlayer insulating layer.

4. The display panel according to claim 3, wherein the conductor layer further comprises a semiconductor layer, the semiconductor layer is disposed in the conductor layer, and a gate insulating layer and a gate electrode metal layer are sequentially disposed on the semiconductor layer.

5. The display panel according to claim 4, wherein a material used as the semiconductor layer is metal oxide, and thicknesses of the semiconductor layer and the conductor layer range from 100 Å to 1000 Å.

6. The display panel according to claim 4, wherein a material used as the gate insulating layer is silicon oxide derivatives, silicon nitride derivatives, or combinations thereof.

7. The display panel according to claim 4, wherein a material used as the gate electrode metal layer is molybdenum, aluminum, copper, titanium, or alloys thereof.

8. The display panel according to claim 1, wherein a thickness of the second sub-metal layer ranges from 5000 Å to 10000 Å, and thicknesses of the first sub-metal layer and the third sub-metal layer range from 100 Å to 500 Å.

9. The display panel according to claim 2, wherein a material of the passivation layer and the interlayer insulating layer is silicon oxide derivatives, silicon nitride derivatives, or combinations thereof, a thickness of the interlayer insulating layer ranges from 2000 Å to 10000 Å, and a thickness of the passivation layer ranges from 1000 Å to 5000 Å.

10. The display panel according to claim 2, wherein a material of the planarization layer is a photoresist material, and a thickness of the planarization layer ranges from 0.5 μm to 3 μm.

11. A manufacturing method of a display panel, comprising:
providing a first sub-metal layer comprising a first surface and a second surface disposed opposite to the first surface;
disposing a second sub-metal layer on the first surface; and
disposing a third sub-metal layer on the second sub-metal layer;
wherein the first sub-metal layer, the second sub-metal layer, and the third sub-metal layer form a metal layer, the display panel has a pixel area and a bonding area disposed adjacent to the pixel area, at least a part of the metal layer is disposed in the bonding area, a material of the first sub-metal layer and the third sub-metal layer is one of molybdenum, titanium, or molybdenum-titanium alloy, and a material of the second sub-metal layer is copper.

12. The manufacturing method according to claim 11, wherein providing the first sub-metal layer comprises:
depositing a conductor layer in the pixel area;
depositing an interlayer insulating layer on the conductor layer; and
depositing the first sub-metal layer on the interlayer insulating layer;
wherein after the first sub-metal layer, the second sub-metal layer, and the third sub-metal layer forming the metal layer, the method further comprises:
depositing a passivation layer, a planarization layer, and a pixel electrode layer on the metal layer in sequence;
etching the overall pixel electrode layer in the bonding area;
depositing a pixel definition layer after finishing the etching process; and
defining a groove in the passivation layer, the planarization layer, and the pixel definition layer by photolithography or etching, wherein the groove extends from a surface of the pixel definition layer to a side surface of the third sub-metal layer of the metal layer away from the first surface.

13. The manufacturing method according to claim 12, wherein after depositing the interlayer insulating layer on the conductor layer, the method further comprises defining a first contact hole and a second contact hole in the interlayer insulating layer in the pixel area by photolithography or etching to make the metal layer in the pixel area connected to the conductor layer through the first contact hole and the second contact hole.

14. The manufacturing method according to claim 12, wherein the conductor layer further comprises a semiconductor layer, the semiconductor layer is disposed in the conductor layer, and a gate insulating layer and a gate electrode metal layer are sequentially disposed on the semiconductor layer.

15. The manufacturing method according to claim 14, wherein a material used as the semiconductor layer is metal oxide, and thicknesses of the semiconductor layer and the conductor layer range from 100 Å to 1000 Å.

16. The manufacturing method according to claim 14, wherein a material used as the gate insulating layer is silicon oxide derivatives, silicon nitride derivatives, or combinations thereof.

17. The manufacturing method according to claim 14, wherein a material used as the gate electrode metal layer is molybdenum, aluminum, copper, titanium, or alloys thereof.

18. The manufacturing method according to claim 12, wherein a thickness of the second sub-metal layer ranges from 5000 Å to 10000 Å, and thicknesses of the first sub-metal layer and the third sub-metal layer range from 100 Å to 500 Å.

19. The manufacturing method according to claim 12, wherein a material of the passivation layer and the interlayer insulating layer is silicon oxide derivatives, silicon nitride derivatives, or combinations thereof, a thickness of the interlayer insulating layer ranges from 2000 Å to 10000 Å, and a thickness of the passivation layer ranges from 1000 Å to 5000 Å.

20. The manufacturing method according to claim 12, wherein a material of the planarization layer is a photoresist material, and a thickness of the planarization layer ranges from 0.5 μm to 3 μm.
